(19) United States
(12) Patent Application Publication
(10) Pub. No.: US 2012/0187373 A1
(43) Pub. Date: Jul. 26, 2012

(54) Stepwise Surface Assembly of Quantum Dot-Fullerene Heterodimers

(75) Inventors: Zhihua Xu, Mineola, NY (US); Mircea Cotlet, Rocky Point, NY (US)

(73) Assignee: BROOKHAVEN SCIENCE ASSOCIATES, LLC, Upton, NY (US)

(21) Appl. No.: 13/357,408

(22) Filed: Jan. 24, 2012

Related U.S. Application Data
(60) Provisional application No. 61/435,590, filed on Jan. 24, 2011.

(51) Int. Cl. H01L 51/30; H01L 51/40; B82Y 99/00; B82Y 40/00

(52) U.S. Cl. 257/14; 438/99; 257/E51.039; 257/E51.002; 977/734; 977/842

(57) ABSTRACT

The present invention relates to high-purity quantum dot-fullerene dimers with controllable linker length and the process of fabricating the same. More particularly, this invention relates to the design, synthesis, and application of high-purity quantum dot-fullerene dimers by applying a novel stepwise surface assembly procedure that ensures the formation of conjugates due to steric repulsion effects between the quantum dots.

### CROSS-REFERENCE TO A RELATED APPLICATION

This application claims the benefit under 35 U.S.C. 119(e) of U.S. Provisional Application No. 61/435,590 filed on Jan. 24, 2011, the content of which is incorporated herein in its entirety.

### STATEMENT OF GOVERNMENT LICENSE RIGHTS

This invention was made with Government support under contract number DE-AC02-98CH10886, awarded by the U.S. Department of Energy. The Government has certain rights in the invention.

### BACKGROUND OF THE INVENTION

I. Field of the Invention

The present invention relates to high purity quantum dot-fullerene conjugates with controllable linker length and the process of fabricating these conjugates. More particularly, this invention relates to the design, synthesis, and application of high-purity quantum dot-fullerene dimers by applying a novel stepwise surface assembly procedure.

II. Background of the Related Art

Molecular electronics have been growing rapidly, to a point where the ambition is to miniaturize conventional electronic devices down to the single molecule scale. One of the essential components of the future molecular circuits is miniaturized power sources. A few reports have addressed this key issue by using a single nanowire as a low power source for nanoelectronics, such as a piezoelectric nanogenerator based on a zinc oxide nanowire, and a solar cell made from a single coaxial silicon nanowire. Organic donor-bridge-acceptor (DBA) supramolecules have been the research interest in molecular electronics due to their rich charge transport mechanisms and ability to control the rate of charge transfer through chemical synthesis. DBA systems can be promising power sources for molecular circuits if they efficiently absorb and convert photons into charge carriers through photo-induced charge transfer (CT).

Recently, semiconductor quantum dots (Qdots) have been combined with other materials such as carbon-based materials, dyes, and TiO₂, or with conductive polymers to yield donor-acceptor (DA) charge transfer systems for dye sensitized cells, light emitting diodes or solar cells.

Quantum dots are, essentially, semiconductor nanocrystals whose excitons are confined in all three spatial dimensions. Consequently, such materials have electronic properties intermediate between those of bulk semiconductors and those of discrete molecules. Generally, the smaller the size of the crystal, the larger the energy band gap, that is, the greater the difference in energy between the highest valence band and the lowest conduction band. Therefore, more energy is needed to excite the dot, and concurrently, more energy is released when the crystal returns to its resting state. For example, in fluorescence based applications, this equates to higher frequencies of light emitted after excitation of the dot as the nanocrystal size grows smaller, resulting in a color shift from red to blue in the light emitted. In addition to such tuning, a main advantage with quantum dots is that, because of the high level of control possible over the size of the nanocrystals produced, it is feasible to have very precise control over the conductive properties of the material. The ability to engineer the band structure of the quantum dots by simply tuning their size and shape opens a wide scope for scientific and technological ventures such as the potential application of semiconductor quantum dots in transistors, solar cells, LEDs, diode lasers and as agents for bioimaging. For instance, the size-dependent spectroscopic properties of semiconductor quantum dots can be utilized to improve the capability of light harvesting and charge transfer in photovoltaic (solar) cells. Multiple exciton generation by one absorbed photon in some quantum dots offers the possibility to greatly enhance the efficiency of photon-to-electron conversion. However, the power conversion efficiency of such Qdot-based devices remains quite low.

Recently, semiconductor Qdots have been combined with fullerenes. Fullerenes are molecules composed entirely of carbon, in the form of a hollow sphere, ellipsoid, or tube. Fullerenes are well known electron acceptors, so that a combination of two has been proposed (Guldi et al., J. Mater. Chem. 15, 114-118 (2005); incorporated herein by reference in its entirety) that would allow photon absorption in quantum dots and photo-induced charge transfer from the quantum dot to the fullerenes, which can result in collection of the separated charge carriers that form photocurrent.

Liu et al., for instance, synthesized CdSe Qdot-Buckminsterfullerene conjugates by exchanging trioctylphosphine oxide (TOPO) ligands on the CdSe quantum dots with fullerene-bound dithiocarbamate ligands. (Liu, et al., J Phys Chem C 111, 17713-17719 (2007); incorporated herein by reference in its entirety). However, the number of fullerenes linked on each quantum dot cannot be well controlled and the quantum dots and fullerenes may crosslink to form higher aggregates during the ligand exchange when this method is used to form Qdot-fullerene conjugates.

Similarly; Xiao et al. investigated charge transfer from monolayer self-assembled CdSe/ZnS core/shell Qdot films and drop-coated fullerene. (Xiao, et al., Modern Phys. Lett. B, 23, 1663-1669 (2009); incorporated herein by reference in its entirety). However, as in Liu et al., the number of fullerene molecules attached and therefore interacting with each quantum dot cannot be readily controlled as shown in FIG. 1 of Xiao et al. This results in an unknown and unevenly controlled distance between Qdot dot and fullerene(s).

### SUMMARY

Having recognized that the conjugate of quantum dot and fullerene should have a predictable and controllable size and number of covalent links in order to control the rate and the magnitude of fluctuations of the photoinduced electron transfer at the level of the individual conjugate, the inventors have developed a reliable stepwise surface assembly method for synthesizing these conjugates. The method provides for a controlled intercomponent distance that, along with the size of the quantum dot, allows one to regulate the strength of photoinduced charge transfer.

It is desirable to have quantum dot-fullerene covalently linked conjugates with predictable and controllable number of covalent links of the same or controllably varying length, and a reliable method for synthesizing these conjugates. In particular, the predictable and controllable covalent linkage of fullerenes to quantum dots would offer new opportunities in the preparation of materials that may produce controllable charge separation and charge-separated states as desired in photovoltaic applications. Thus, synthesizing a structure with a fixed, and controllable distance between the two electroactive components may prevent the undesired loss of excitation energy via alternative radiation and radiationless decay channels, while making possible efficient and controllable charge transfer and charge separation.

A present semiconducting conjugate comprises a quantum dot (Qdot), a fullerene, and a covalent linker formed between the quantum dot and the fullerene, where the covalent linker can be an aminoalkanethiol, or other molecule with two distinct functional groups, one for bonding to the fullerene and one for bonding to the Qdot. In one example, one fullerene may be connected to one quantum dot by one linker, with the distance between the fullerene and the quantum dot being no more than approximately the length of the linear linker used (end-to-end). Alternatively, in another example, a fullerene may be connected to a quantum dot by more than one linker, with the distance between the fullerene and the quantum dot still being no more than approximately the length of the linear linker used (end-to-end). In both cases, the stoichiometry of the quantum dot-fullerene conjugate is one-to-one.

The first component of the conjugate is a quantum dot. It may be any particle with size-dependent properties, e.g., chemical, optical, and electrical properties, along three orthogonal dimensions such as spheroids, rods, and tripods, although cubes disks, pyramids and other shapes may also be used, depending on the application, as long as the desired quantized properties are maintained. A quantum dot typically comprises a core of one or more first materials and can optionally be surrounded by a shell of a second material.

A core of the quantum dot can substantially include a homogeneous material and may comprise inorganic crystals of Group IV semiconductor materials, Group II-VI semiconductor materials, Group III-V semiconductor materials, Group IV-VI semiconductor materials, mixtures thereof; and tertiary or alloyed compounds of any combination between or within these groups. In one embodiment, the core of the quantum dot is made from CdSe.

Quantum dots may optionally comprise a shell of a second material that surrounds the core. A shell may comprise Group II-VI semiconductor materials, Group III-V semiconductor materials, mixtures thereof; and tertiary or alloyed compounds of any combination between or within these groups. In one embodiment, the shell of the quantum dot is made from ZnS so that molecular linkers containing thiol groups can coordinate with the metal atom (Zn).

It will be appreciated by one of ordinary skill in the art that quantum dots can exist in a variety of shapes, including but not limited to spheroids, rods, or tripods. While these shapes can affect the physical, optical, and electronic characteristics of quantum dots, the specific shape does not bear on the qualification of a particle as a quantum dot. For convenience, the size of quantum dots will be described in terms of a diameter. A quantum dot will typically be in a size range between about 1 nm and about 100 nm in diameter. Preferably, the size will be between about 1 nm and about 10 nm. Rods may have extended sizes in one dimension, up to 100 nm.

The second component of the conjugate is a fullerene. It may comprise a core and optionally one or more surface ligands linked to the fullerene core to form a “polyfunctionalized” fullerene. The core of the fullerene is a carbon molecule having an even number of carbon atoms arranged in the forth of a closed hollow cage, typically spheroid, wherein the carbon-carbon bonds define a polyhedral structure. For example, the fullerene may be selected from C₆₀, C₇₀, C₇₆, C₈₀, C₈₄, and C₁₂₀, with C₆₀ being preferred due to its electronic properties. Optionally, a fullerene may have between 2 and 32 functional groups, independently selected from the group consisting of carboxyl, amino and hydroxyl. In one particular embodiment, C₆₀ is functionalized with malonic acid hexadduct C₆₀[C(COOH)₂]₆, (FMH).

The third component of the conjugate is a linker between the quantum dot and the fullerene. The linker has two different functional groups on either end, one to bond to the Qdot and one to bond to the fullerene. In addition, the linker functional groups should be such that they do not interact with each other, which could otherwise lead to undesired crosslinking between the linker molecules. In one embodiment, an aminoalkanethiol linker is selected from 11-Amino-1-undecanethiol, 8-Amino-1-octanethiol, 6-Amino-1-hexanethiol, 16-Amino-1-hexadecanethiol, Amino-EGG-undecanethiol, or Amino-EGG-hexadecanethiol. An exemplary complete fullerene-quantum dot conjugate is illustrated in FIG. 1.

In another embodiment, the semiconducting conjugate of quantum dot and fullerene may be synthesized on the surface of an acceptable solid support material by a stepwise assembly method comprising: (1) preparing a surface of a solid support, (2) activating the surface, e.g., by silanization; (3) immobilizing a fullerene or a derivative thereof on to the activated surface, (4) covalently bonding one end of a linker to the attached fullerene, and (5) attaching a quantum dot to the opposite side of the linker via covalent metal-ligand interaction to produce a quantum dot-fullerene conjugate on the surface of the solid support.

However, the conjugates described herein are not limited to compositions of the preferred embodiment and may comprise any compositions made apparent from the following detailed description, which is to be read in conjunction with the accompanying drawings. The scope of the invention will be pointed out in the claims.

### BRIEF DESCRIPTION OF THE DRAWINGS

FIG. 1 illustrates linking moieties in an exemplary Qdot-fullerene dimer conjugate.

FIGS. 2A and 2B illustrate a Q-dot fullerene dimer conjugate immobilized on the solid support.

FIG. 3 illustrates a step-wise assembly method in preparation of quantum dot-linker-fullerene dimeric conjugates on the solid support.

FIG. 4A illustrates a structure of the fullerene malonic acid hexadduct (FMH).

FIG. 4B illustrates an exemplary structure of an aminoalkanethiol.

FIG. 4C illustrates an exemplary structure of the Qdot with CdSe core, ZnS shell, and carboxyl surface ligands.

FIG. 5 illustrates UV-vis spectra (solid lines) of FMH, and of quantum dots with emission colors at 525 nm (QD525), 565 nm (QD565), and 605 nm (QD605), and photoluminescence (PL) spectra (dashed lines) of the same quantum dot compounds.

FIG. 6A illustrates quenching by electron transfer of PL spectra of QD 605 when mixed with FMH in water at various concentrations (0-4.8 μM against 80 nM QD605).

FIG. 6B illustrates quenching by electron transfer of PL spectra of QD 605 when mixed with 0-4.8 μM FMH in the presence of EDC and 6AHT linker.

FIG. 7 illustrates confocal FLIM images of (a) silanized glass treated with QD605, (b) silanized glass treated with FMH and EDC, followed by treatment with QD605, and (c) silanized glass treated with FMH and EDC, followed by treatment with 16AHT and EDC, and finally followed by treatment with QD605.

FIG. 8 illustrates PL intensity time trajectories and PL intensity histograms of a quantum dot QD605 (A and B), and of quantum dot-fullerene dimer conjugates QD605-16AT-FMB (C and D) and QD605-6AT-FMH (E and F).

FIG. 9 illustrates histograms of single molecule PL lifetimes from quantum dots QD605 (a); from quantum dot fullerene dimers of the type QD605-16AHT-FMH (b); of the type QD605-11AUT-FMH (c); of the type QD605-6AHT-FMH (d); and from quantum dots QD605 spincoated on a FMH film without using any aminoalkene linker (e). (f) Electron transfer rate, k_{ET}, vs. linker length, R, for quantum dot-fullerene dimers of the type QD605-linker-FMH.

FIG. 10 illustrates histograms of single molecule PL lifetimes of quantum dots (grey color) and of Qdot-linker-FMH dimers (black color) for quantum dots of varying color (size) such as: (a) QD605, (b) QD565, and (c) QD525. (d) Electron transfer rate, k_{ET}, vs. quantum dot core size for QD-linker-FMH dimers using 16 AHT linker.

### DETAILED DESCRIPTION

The present class of novel materials comprises a semiconducting dimeric conjugate made of a quantum dot and a fullerene covalently linked in a predictable and controllable manner, and a method of stepwise synthesis of such materials on a solid support surface. The present objectives will become more apparent from the following description and illustrative embodiments which are described in detail with reference to the accompanying drawings.

In its simplest form, the present invention includes a fullerene and a quantum dot connected by one or more linear linkers. The linker may also be branched as long as the linker has two different functional groups on either end, one to bond to the Qdot and one to bond to the fullerene. In one example, a fullerene may be connected to a quantum dot by one linker, with the distance between the fullerene and the quantum dot being no more than approximately the length of the linear linker used (end-to-end):

Cₙ-LINKER-Qdot

Alternatively, in another example, a fullerene may be connected to a quantum dot by more than one linker, with the distance between the fullerene and the quantum dot still being no more than approximately the length of the linear linker used (end-to-end).

As used herein, the term “quantum dot,” “Qdot,” and “nanocrystal” are synonymous and refer to any particle with size-dependent properties, e.g., chemical, optical, and electrical properties, along three orthogonal dimensions. A quantum dot typically comprises a core of one or more first materials and can optionally be surrounded by a shell of a second material.

A core of the quantum dot can substantially include a homogeneous material. It can be crystalline, polycrystalline, or amorphous. A core may also be defect-free or it may contain a range of defect densities, such as any crystal stacking error, vacancy, insertion, or impurity entity, e.g., a dopant, placed within the material forming the core. Impurities can be atomic or molecular.

A core of a quantum dot may comprise inorganic crystals of Group IV semiconductor materials including but not limited to Si, Ge, and C; Group II-VI semiconductor materials including but not limited to ZnS, ZnSe, ZnTe, ZnO, CdS, CdSe, CdTe, CdO, HgS, HgSe, HgTe, HgO, MgS, MgSe, MgTe, MgO, CaS, CaSe, CaTe, CaO, SrS, SrSe, SrTe, SrO, BaS, BaSe, BaTe, and BaO; Group III-V semiconductor materials including but not limited to AlN, AlP, AlAs, AlSb, GaN, GaP, GaAs, GaSb, InN, InP, InAs, and InSb; Group IV-VI semiconductor materials including but not limited to PbS, PbSe, PbTe, and PbO; mixtures thereof; and tertiary or alloyed compounds of any combination between or within these groups.

Quantum dots may optionally comprise a shell of a second material that surrounds the core. The shell material is preferably an inorganic semiconductor with a bandgap that is larger than that of the core material. The shell material may be optionally selected to have an atomic spacing close to that of the core material. The shell may also contain a metallic species that coordinates with a thiolated linker, e.g., Zn in the case of a ZnS core.

A shell may comprise Group II-VI semiconductor materials including but not limited to ZnS, ZnSe, ZnTe, ZnO, CdS, CdSe, CdTe, CdO, HgS, HgSe, HgTe, HgO, MgS, MgSe, MgTe, MgO, CaS, CaSe, CaTe, CaO, SrS, SrSe, SrTe, SrO, BaS, BaSe, BaTe, and BaO; Group III-V semiconductor materials including but not limited to AlN, AlP, AlAs, AlSb, GaN, GaP, GaAs, GaSb, InN, InP, InAs, and InSb; mixtures thereof; and tertiary or alloyed compounds of any combination between or within these groups. A shell may optionally comprise multiple materials, in which different materials are stacked on top of each other to form a multi-layered shell structure.

The shell may substantially surround the outer surface of the core, e.g., substantially all surface atoms of the core are covered with shell material. Alternatively, the shell may only partially surround the outer surface of the core, e.g., partial coverage of the surface core atoms is achieved. In addition, it is possible to create shells of a variety of thicknesses, which can be defined in terms of the number of monolayers of shell material that are bound to each core. For certain applications, shells will preferably be of a thickness between approximately 0 and 10 monolayers. For certain applications, shell thickness will preferably range between approximately 0.1 nm and 10 nm.

It will be appreciated by one of ordinary skill in the art that quantum dots can exist in a variety of shapes, including but not limited to spheroids, rods, tripods, etc. While these shapes can affect the physical, optical, and electronic characteristics of quantum dots, the specific shape does not bear on the qualification of a particle as a quantum dot. For convenience, the size of quantum dots will be described in terms of a diameter, which is generally the diameter of a cross section taken through the dot at its minimum circumference. For example, a nanorod's diameter would be the diameter of the rod's cross section perpendicular to the long direction. A quantum dot will typically be in a size range between about 1 nm and about 100 nm in diameter. Preferably, the size will be between about 1 nm and about 10 nm.

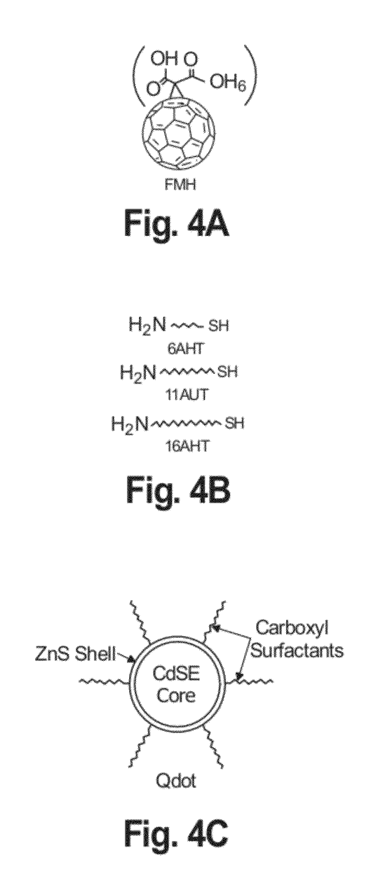

A quantum dot may optionally comprise a ligand layer made from one or more surface ligands, e.g., organic molecules, surrounding a core or a core/shell combination, according to some embodiments of the invention. One example of such a quantum dot is shown in FIG. 4C. A quantum dot comprising a ligand layer may or may not also comprise a shell. The surface ligands of the ligand layer may bind, either covalently or non-covalently, to either the core or the shell material or both (in the case of an incomplete shell), although covalent bonding is preferred. The ligand layer may comprise a single type of surface ligand, e.g., a single molecular species, or a mixture of two or more types of surface ligands, e.g., two or more different molecular species. A surface ligand can have an affinity for, or bind selectively to, the quantum dot core, shell, or both at least at one point on the surface ligand. The surface ligand may optionally bind at multiple points along the surface ligand.

The surface ligand may optionally contain one or more additional active groups that do not interact specifically with the surface of the quantum dot. The surface ligand may be substantially hydrophilic, substantially hydrophobic, or substantially amphiphilic. Examples of the surface ligand include but are not limited to an isolated organic molecule, a polymer (or a monomer for a polymerization reaction), an inorganic complex, and an extended crystalline structure. In one embodiment, the quantum dot has a core and a shell such as CdSe/ZnS and a surface ligand layer made from species with exposed carboxyl active groups. (For example, carboxyl surfactants are shown in FIG. 4C.)

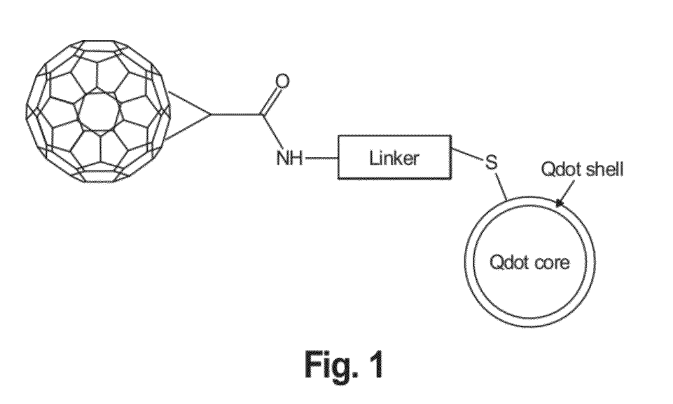

The present linker(s) are linked to the quantum dot via the linking moieties as shown in FIG. 1A. In some embodiments, the linking moieties of the linker may be derived from various linear or branched sulfhydryl group(s) on one end and an amine group(s) on the opposing end, whereas the linking intermediate may have a simple hydrocarbon moiety of the formula —CₙH₂, where n may range from 2-25, preferably from 2 to 16, and more preferably from 2 to 8. The linking intermediate can also be a large hydrocarbon group (substituted or unsubstituted) of at least 25 carbon atoms, and can contain repeating moieties. Persons of skill in the art will be able to determine whether a composition of more similar linkers or a mixture of varied linkers is more appropriate for a particular application. In one particular embodiment, the linker is derived from an aminoalkanethiol of the formula:

H₂N (CH₂)ₙSH

In particular embodiments, the aminoalkanethiol may be 11-Amino-1-undecanethiol (see FIG. 4B), 8-Amino-1-octanethiol, 6-Amino-1-hexanethiol (see FIG. 4B), 16-Amino-1-hexadecanethiol (see FIG. 4B), Amino-EG6-undecanethiol, or Amino-EG6-hexadecanethiol.

The present semiconducting conjugate further comprises a fullerene coupled on the opposite side of the linker. The present linker(s) may couple to the fullerene via the linking moieties as shown in FIG. 1B.

A fullerene comprises a core and optionally one or more surface ligands linked to each fullerene core, also known as “polyfunctionalized” fullerenes. The core of the fullerene is a carbon molecule having an even number of carbon atoms arranged in the form of a closed hollow cage, typically spheroid, wherein the carbon-carbon bonds define a polyhedral structure. For example, the fullerene may be selected from C₆₀, C₇₀, C₇₆, C₈₀, C₈₄, or C₁₂₀, with C₆₀ being preferred due to its electronic properties. Optionally, a fullerene may have between 2 and 32 functional groups, independently selected from the group consisting of carboxyl, amino and hydroxyl. For example, the carboxyl group may be bonded to a carbon atom of the fullerene; similarly the nitrogen atom or oxygen atom of the hydroxyl group may be bonded to a carbon atom of the fullerene. Alternatively, the functional group may be indirectly bonded to one or more carbons of the fullerene. Examples of polyfunctionalized fullerenes include, but are not limited to, C₆₀(—COOH)₄₋₈. Similarly, other fullerenes with relatively small functional groups or addends such as amido, alkoxy, and halides have been described. See, e.g., U.S. Pat. No. 5,177,248; European Application No. 546,718; European Application No. 575,129. In some embodiments, the fullerenes are functionalized with dicarboxylic acid, e.g., C₆₀[C(COOH)₂]₁₋₈, such as malonic acid, glutaric acid, pimelic acid, azelaic acid, and other similar acids. In one particular embodiment, C₆₀ is functionalized with malonic acid hexadduct C₆₀[C(COOH)₂]₆ as shown in FIG. 4A. An exemplary complete fullerene-quantum dot conjugate of the present invention is shown in FIG. 1. Without being bound by any particular theory, in this exemplary embodiment, the fullerene and the quantum dot, each having identical (in this case, carboxyl) functional groups, repel each other due to steric influences and only in the presence of the linker do the two form a dimer having controllable and predictable properties.

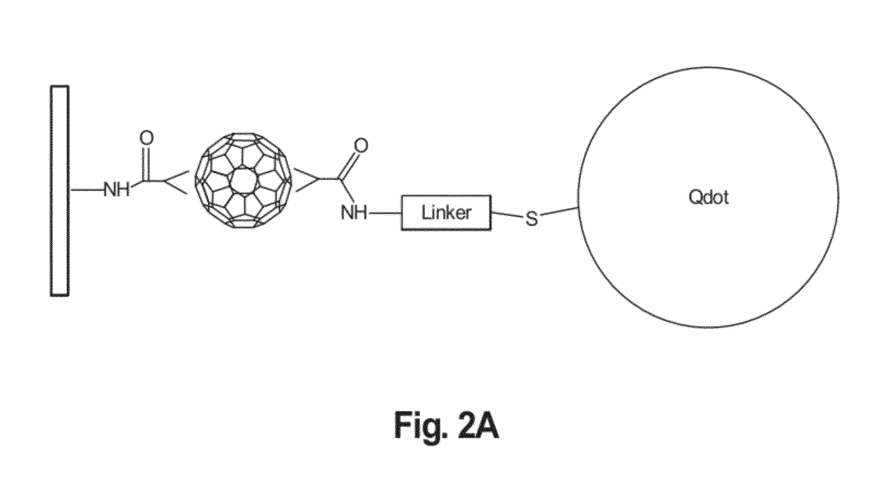

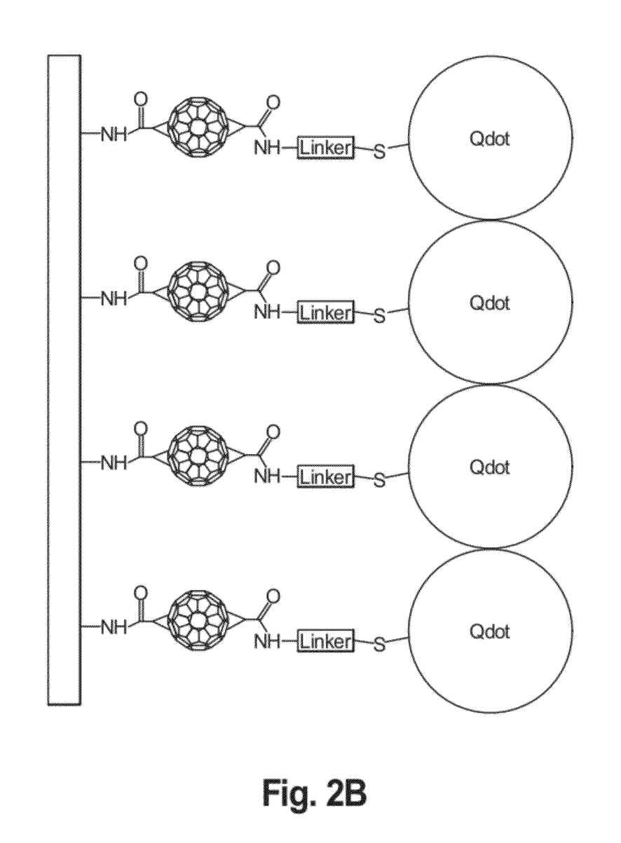

The present semiconducting conjugate may further be optionally coupled to a solid support where the conjugate is immobilized via a linking moiety between the fullerene and the solid support as shown in FIG. 2A. A dimeric conjugate may form on a solid support if attached in the sequence described herein below, i.e., surface→fullerene→linker→Qdot, due to steric repulsing effect of the quantum dots because Qdots are usually much larger that the fullerene, as shown in FIG. 2A. A plurality of conjugates immobilized on the solid support may form a bilayer as shown in FIG. 2B.

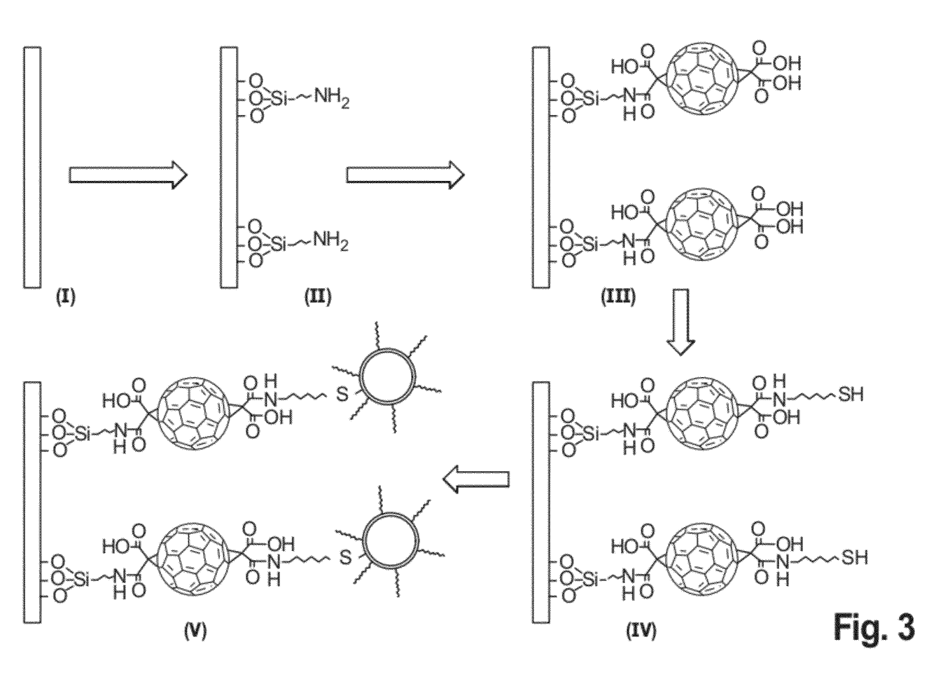

In another embodiment, the semiconducting conjugate of quantum dot and fullerene may be synthesized on the surface of an acceptable solid support material by a stepwise assembly method having the steps of: (1) preparing a surface of a solid support, (2) activating the surface on the solid support by silanization, (3) coupling a fullerene or a derivative thereof on to the activated surface of the solid support, (4) coupling one end of a linker on to the fullerene attached to the surface of the solid support, and (5) coupling a quantum dot to the opposite side of the linker to produce a quantum dot-fullerene conjugate on the surface of the solid support. The steps are summarized in FIG. 3. The use of a stepwise surface assembly procedure which starts with fullerene and ends with quantum dots ensures the formation of dimeric conjugates due to steric repulsing effects of the quantum dots because the quantum dots are usually much larger, e.g., 10 nm, than the fullerenes, e.g., 1 nm. Other processes, e.g., attaching the fullerene to the quantum dot as shown in Liu et al. and Xiao et al., would result in conjugates with uncontrollable stoichiometry.

### (1) Preparing a Surface on a Solid Support

In a preferred embodiment, the conjugate is synthesized with the aid of a solid support system. As used in this specification and the appended claims, the term “solid support” is used to denote the matrix upon which any number of chemical reactions may be performed. In particular, as defined by IUPAC, solid support includes any insoluble, functionalized material to which library members or reagents may be attached (often via a linker).

In one embodiment, the solid support may be made from silicon dioxide such as glass, fused quartz, fumed silica, colloidal silica, silica gel, or aerogel. However, other polymeric materials and metal oxides are also envisioned as long as the substrate is in particles of physical size and shape that permit ready manipulation and rapid filtration from liquids, it is physically stable, it is inert to all reagents and solvents used during the synthesis, and it can be readily modified to allow attachment of the first entity by a covalent bond, e.g., silanization. A list of exemplary solid support materials is provided in Kates, S. A. et al., Solid-Phase Synthesis—A practical guide, pp. 1-78, CRC Press, 2000, the disclosure of which is incorporated herein by reference in its entirety.

Once the solid support is selected, typically the surface of the solid support may require preparation before it is activated to remove any organic residues and, optionally, to hydroxylate the surface of the selected solid support, e.g., by adding (—OH) groups, thus making the surface extremely hydrophilic. For example, if the solid support chosen is glass, it may be treated with a solution made from hydrogen peroxide (H₂O₂) and sulfuric acid (H₂SO₄), also known as Piranha solution, for the amount of time necessary to, for instance, hydroxylate the surface of glass, i.e., adding silanol (Si—OH) groups. In one embodiment, the sufficient time is about 5 minutes to about 30 minutes, preferably about 15 minutes, and the solution has a mixture of 2:1 to 7:1 of concentrated sulfuric acid to hydrogen peroxide solution, with about 3:1 being preferred (about 30% (v/v) of hydrogen peroxide and about 70% (v/v) of sulfuric acid). However, other solutions for preparing the solid support are also envisioned and are well known in the art, such as sodium hydroxide, sulfuric acid, or chromic acid.

### (2) Activating the Surface on the Solid Support by Silanization

In accordance with a preferred embodiment, the method of synthesizing quantum dot-fullerene dimer conjugates comprises activating the surface of the solid support by silanization, i.e., treating the prepared surface with an activating agent to produce an organofunctional alkoxysilane surface.

The activating agent may be selected from an aminosilane (see Formula (1)), a glycidoxysilane, or a mercaptosilane. The aminosilane activating agent includes 3-aminopropyl-triethoxysilane (APTES), 3-aminopropyl-diethoxy-methylsilane (APDEMS), 3-aminopropyl-dimethyl-ethoxysilane (APMES), or 3-aminopropyl-trimethoxysilane (APTMS). The glycidoxysilane activating agent includes 3-glycidoxypropyl-dimethyl-ethoxysilane (GPMES). The mercaptosilane activating agent includes 3-mercaptopropyl-trimethoxysilane (MPTS) or 3-mercaptopropyl-methyl-dimethoxysilane (MPDMS). In a preferred embodiment, the activating agent is 3-aminopropyl-trimethoxysilane (APTMS) and the solid support is made from a silicon oxide based material.

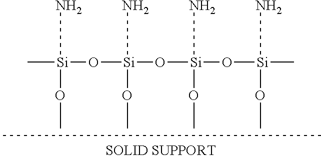

Typically, activating the solid support may include combining the solid support with the activating agent in a water-free environment and subsequently heat treating the combination of the solid support with the activating agent for a time that is sufficient to activate the solid support. The post-activation surface may be optionally rinsed with deionized water to remove any unreacted/unbound activating agents. According to a preferred embodiment, in the method of synthesizing quantum dot-fullerene dimer conjugates where the activating agent is 3-aminopropyl-trimethoxysilane (APTMS) and the solid support is made from a silicon oxide based material, e.g., glass, activating the solid support may include combining the solid support with the activating agent in a water-free environment for about 15 to 20 minutes and subsequently heat treating the combination of the solid support with the activating agent in an oven, e.g., at 90° C., for a time that is sufficient to activate the solid support, e.g., about 1 hour. The post-activation surface may be optionally rinsed with deionized water to remove any unreacted/unbound activating agents. Although one exemplary procedure is provided, those skilled in the art would understand that other parameters such as time, temperature, pressure, etc., may be employed to arrive at the same result depending on the desired setup and the selected activating agent.

### (3) Fullerene Immobilization

Once the surface of solid support is activated, the fullerene is ready to be immobilized on that surface by a covalent link. In one embodiment, the fullerene coupling may be accomplished by soaking the organofunctional alkoxysilane surface of the solid support with a functionalized fullerene in the presence of a crosslinking agent. The crosslinking agent may be necessary to accelerate a rate-limiting step such as an amide bond formation between a carboxyl group and a primary amine.

For example, in one particular embodiment, the functionalized fullerene may have one or more exposed carboxyl groups, e.g., a fullerene-malonic acid-hexadduct (FMH) of formula C₆₀[C(COOH)₂]₆. The cross-linking agent in such instance may be any zero-length agent that can react with a carboxyl group to form an amine-reactive O-acylisourea intermediate. If this intermediate does not encounter an amine, it will hydrolyze and regenerate the carboxyl group. However, in the presence of a primary amine, a cross-linking amide bond will form. 1-Ethyl-3-[3-dimethylaminopropyl]carbodiimide hydrochloride (EDC) is one example of such a zero-length cross-linking agent used to couple carboxyl groups to primary amines

### (4) Linker Bonding on the Immobilized Fullerene

In accordance with one embodiment, once the fullerene is immobilized on to the surface of the solid support, it may be covalently bonded to a linker of predefined length. The bonding is achieved by treating the immobilized fullerene with a linker in the presence of a cross-linking agent. The linker may have two functional groups. In a linear linker, each functional group may be located at each opposing end. In a preferred embodiment, one functional group is a sulfhydryl group and the other functional group is an amine group on the opposing end, whereas the linking intermediate may have a simple hydrocarbon moiety of the formula where n may range from 2-100. In a preferred embodiment, the linker is an aminoalkanethiol (hydrochloride) that includes, but is not limited to, 11-Amino-1-undecanethiol hydrochloride, 8-Amino-1-octanethiol hydrochloride, 6-Amino-1-hexanethiol hydrochloride, 16-Amino-1-hexadecanethiol hydrochloride, Amino-EG6-undecanethiol hydrochloride, or Amino-EG6-hexadecanethiol hydrochloride. Similarly to the fullerene immobilization, the covalent bonding of the linker is done in the presence of a zero-length crosslinking agent such as 1-ethyl-3-(3-dimethylaminopropyl)carbodiimide hydrochloride (EDC). Once again, the cross-linking agent reacts with a carboxyl group on the fullerene to form an amine-reactive O-acylisourea intermediate. In the presence of a primary amine of the linker, a crosslinking amide bond forms. Preferably, once the bond is formed, the solid support assembly, i.e., immobilized fullerene with the linker, is washed with the deionized water to remove any unbound linkers.

### (5) Quantum Dot Immobilization to Produce a Quantum Dot-Fullerene Conjugate

Finally, in order to produce a conjugate of quantum dot-fullerene, the solid support with the immobilized fullerene and the linker may be treated with a carboxyl-ended water-soluble quantum dot that rapidly reacts with the sulfhydryl group to form a final conjugate by a metal-ligand type interaction. Treating the solid support assembly with the quantum dot(s) in the last step ensures the formation of dimeric conjugates due to steric repulsion effects between the quantum dots, and avoids clusters containing one quantum dot and the unknown plurality of fullerenes observed in the prior art.

### EXAMPLES

The examples set forth below also serve to provide further appreciation of the invention but are not meant in any way to restrict the scope of the invention.

### Example 1

Single molecule fluorescence measurements were conducted with a custom-built confocal scanning microscope based on inverted Olympus IX81 coupled with pulse laser excitation. 920-nm infrared laser output was provided by a mode-locked Ti:Sapphire femtosecond laser (Tsunami 3960, Spectra-Physics) pumped by 10-W diode laser (Millennia Pro, SpectraPhysics) and was passed through a frequency doubler and pulse picker to generate a 460-nm laser beam with 8 MHZ repetition rate. The laser beam was then reflected by a dichroic filter (Di01-R442, Semrock) and focused on the sample surface with a 100×1.4 NA oil immersion objective (Olympus). Fluorescence from the sample was passed through the same objective and the dichroic filter, and was filtered by a 75-μm pinhole and a bandpass filter (FF01-583/120, Semrock) before it was collected by an avalanche photodiode (APD). Time-correlated single photon counting unit PicoHarp 300 (PicoQuant) was used for the data acquisition with time-tagged time-resolved (TTTR) mode. Software Symphotime (V5.1.3) was used for the equipment operation and data analysis.

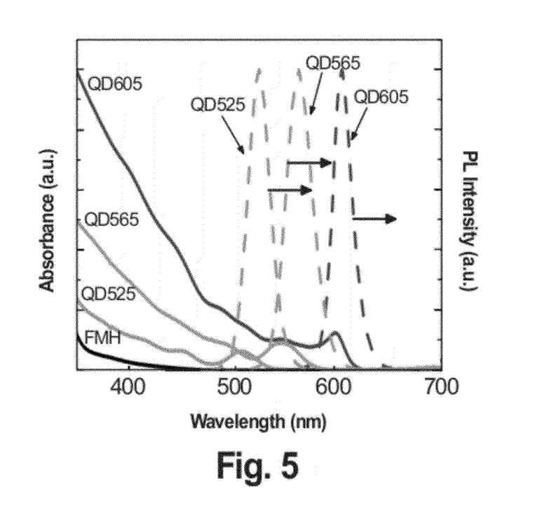

The electronic spectra of FMH and Qdots of various colors (sizes) are shown in FIG. 5. Due to lack of overlap between the photoluminescence (PL) spectra of Qdots and the absorption spectrum of FMH, energy transfer from Qdots to FMH is ruled out so that charge transfer is only possible from Qdot to FMH upon ultraviolet-to-blue light excitation, for example at 460 nm. Considering the positioning of the electronic energy levels of CdSe Qdots (conduction band −4.3 eV, valence band −6.4 eV for a 4.4-nm sized CdSe Qdot) and fullerene C₆₀ (lowest unoccupied molecular level, LUMO, −4.7 eV, highest occupied molecular level, HOMO, −6.8 eV), the photoprocess is narrowed further to electron transfer and unfavorable hole transfer.

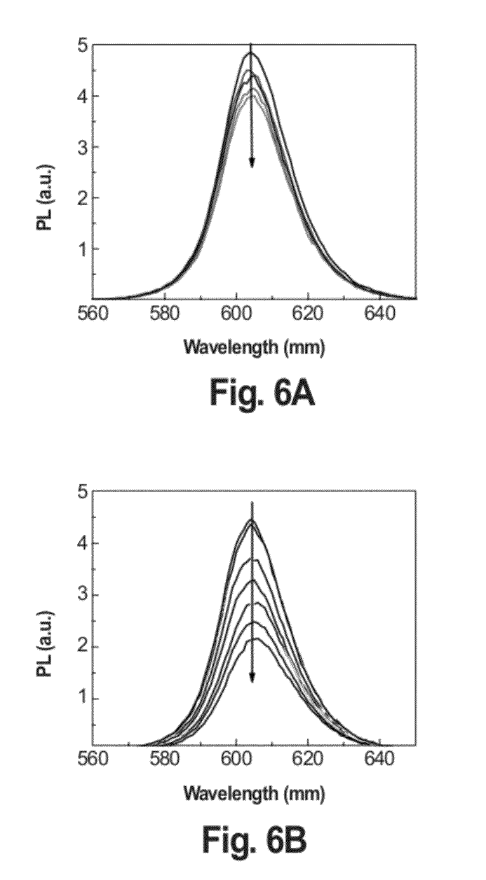

When mixed in aqueous solution, diffusion-controlled PL quenching of Qdots such as QD605 by FMH is low (15% based on the estimated reduction in PL, see FIG. 6A), presumably due to the weak electronic coupling between Qdots and FMH, since both have negative carboxyl groups at the surface. To enhance the electronic coupling, aminoalkanethiols linkers of varying length (see FIG. 4B) were used to conjugate Qdot and FMH components: 16-Amino-1-hexadecanethiol hydrochloride (16AHT), 11-amino-1-undecanethiol hydrochloride (11AUT), and 6-Amino-1-hexanethiol hydrochloride (6AHT). Specifically, the amine end of the linker couples with a carboxyl group of the FMH through a standard coupling reaction assisted by 1-Ethyl-3-(3-dimethylaminopropyl)-carbodiimide (EDC), while the thiolated end of the linker binds to the ZnS surface of the core/shell Qdot. The covalent conjugation of quantum dot with the fullerene in solution enhances quenching of Qdot by FMH in solution, up to 42% for the shortest linker (see FIG. 6B). However, the unavoidable crosslinking between Qdots and FMH in solution results in the production of structures other than only quantum dot-fullerene heterodimers, such as isomers, homodimers, trimers, and even larger structures, making Qdot-FMH conjugates highly heterogeneous. The inventive stepwise surface-based assembly was proposed to circumvent this heterogeneity.

### Example 2

A stepwise surface-based assembly procedure was designed that yields Qdot-FMH dimers of high purity (see FIG. 3) and includes the following: (1) glass cleaning, (2) surface silanization, (3) fullerene malonic acid hexadduct (FMH) immobilization, (4) linker bonding, and (5) quantum dot conjugation.

In detail, glass slides (25×25 mm) were first cleaned by soaking in Piranha solution, made of 30% (v/v) Hydrogen Peroxide (Sigma Aldrich, St. Louis, Mo.) and 70% (v/v) Sulfuric Acid (Sigma Aldrich, St. Louis, Mo.), for 15 minutes and then thoroughly rinsed by deionized water, e.g., Milli-Q water. After drying by nitrogen gas, the cleaned glass slides were placed in a Petri dish with 20 μl 3-Aminopropyltrimethoxysilane (APTMS) (Sigma Aldrich, St. Louis, Mo.) and the dish was then covered and kept in a desiccator under a vacuum of 20 KPa for 15-120 minutes, followed by heat treatment in an oven (90° C.) for 1 hour. The amine-modified glass slides were then covered by 100 μl mixed aqueous solution of the fullerene-malonic acid-hexadduct (FMH) C₆₀[C(COOH)₂]₆ (0.04 mg/ml) and 1-ethyl-3-(3-dimethylaminopropyl)carbodiimide hydrochloride (EDC) (Sigma Aldrich, St. Louis, Mo.) (5 mg/ml) for 30 minutes. The surface of the glass slides was further treated by 100 μl mixed aqueous solutions of EDC (5 mg/ml) and different aminoalkanethiols (0.01 mg/ml): 6-Amino-1-hexanethiol hydrochloride (6AT), 11-Amino-1-undecanethiol hydrochloride (11AT), and 16-Amino-1-hexadecanethiol hydrochloride (16AT) (Dojindo, Rockville, Md.) for 30 minutes. Finally, the glass surface was treated with diluted aqueous solution of one of three types of carboxyl-ended core/shell CdSe/ZnS quantum dots: a CdSe/ZnS quantum dot with nominal core diameter of about 4.4 nm and an emission wavelength of 605 nm (denoted as QD605), a CdSe/ZnS quantum dot with nominal diameter of about 3.2 nm and an emission wavelength of 565 nm (denoted as QD565), and a CdSe/ZnS quantum dot with nominal diameter of about 2.6 nm and an emission wavelength of 525 nm (denoted as QD525) (0.5 nM) for 1 minute. The functionalized quantum dots are commercially available from Invitrogen® in these colors or from other manufactures with similar colors/diameters. Following each of last three mentioned steps, the glass surface was thoroughly rinsed by deionized water to remove excess chemicals. The conjugates synthesized using the stepwise method outlined above are summarized in Table 1.

TABLE 1
Conjugates synthesized using the stepwise
method described in Example 2

| | Fullerene | Linker | Quantum dot |
|---|---|---|---|
| 1 | C₆₀[C(COOH)₂]₆ | 6AT | QD605 |
| 2 | C₆₀[C(COOH)₂]₆ | 6AT | QD565 |
| 3 | C₆₀[C(COOH)₂]₆ | 6AT | QD525 |
| 4 | C₆₀[C(COOH)₂]₆ | 11AT | QD605 |
| 5 | C₆₀[C(COOH)₂]₆ | 11AT | QD565 |
| 6 | C₆₀[C(COOH)₂]₆ | 11AT | QD525 |
| 7 | C₆₀[C(COOH)₂]₆ | 16AT | QD605 |
| 8 | C₆₀[C(COOH)₂]₆ | 16AT | QD565 |
| 9 | C₆₀[C(COOH)₂]₆ | 16AT | QD525 |

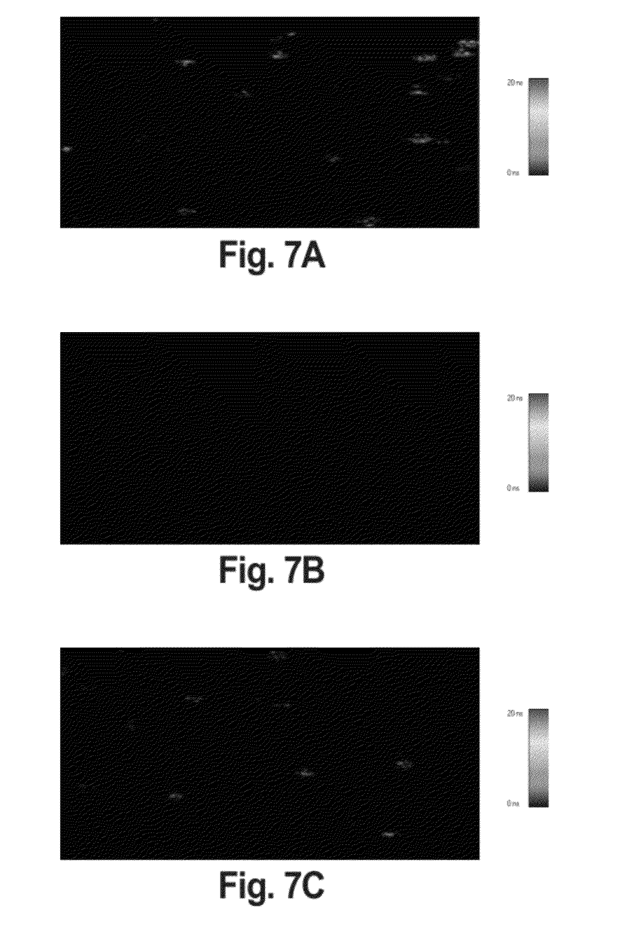

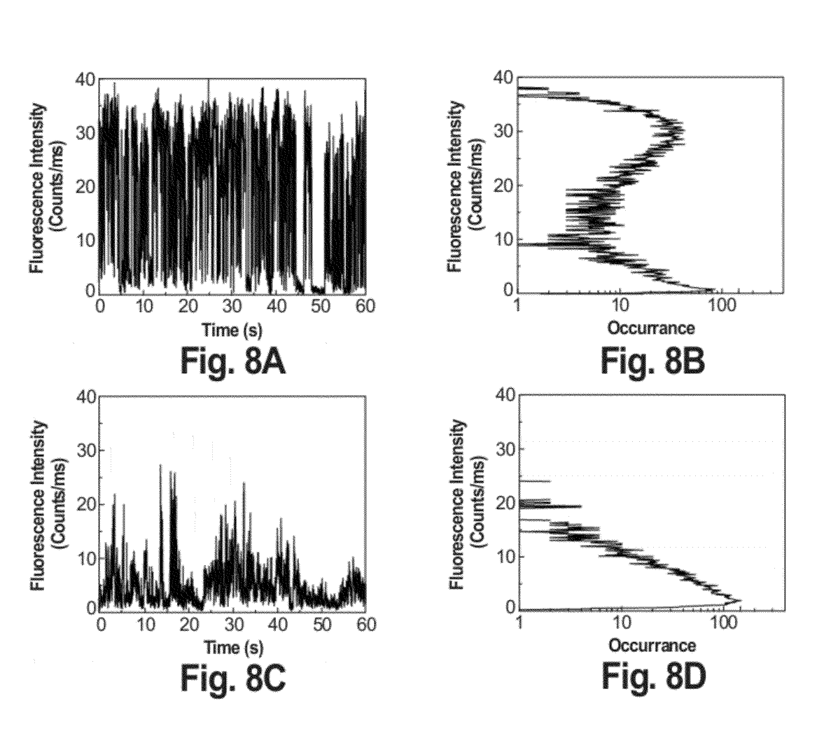

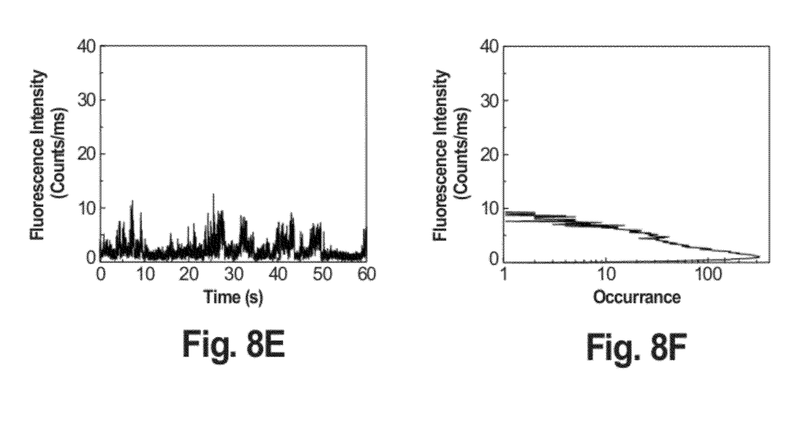

Control experiments using confocal fluorescence microscopy were performed to clearly demonstrate that nonspecific binding of Qdots to surface immobilized FMH molecules in the absence of aminoalkanethiols linkers is negligible (see FIG. 7).

### Example 3

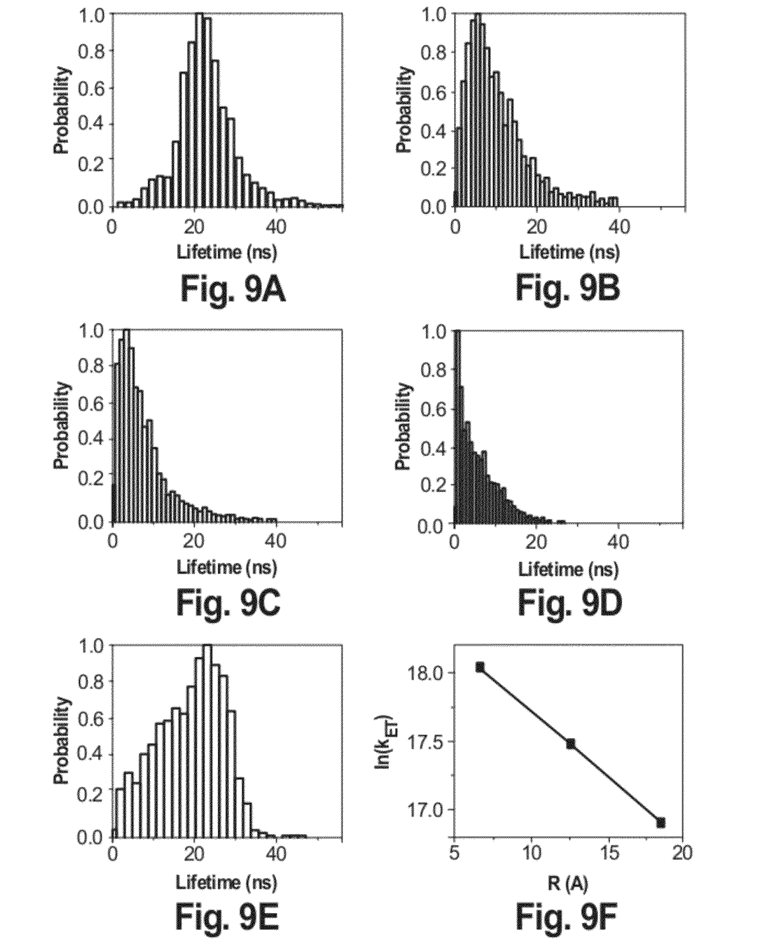

FIG. 9 demonstrates how the use of the quantum dot-linker-fullerene dimer conjugate structure allows control of the electron transfer properties, both the magnitude of the rate and of rate fluctuation. FIGS. 9A-9D are PL lifetime histograms measured from individual quantum dots (a), individual quantum dot QD605-linker-fullerene dimeric conjugates with linker 16AHT (b), 11AUT (c), and 6AHT (d), and from individual QD605 spincoated on a layer of fullerenes without using linkers (e). For QD605 isomers, the lifetimes distribute symmetrically around 20 ns (standard deviation, σ˜6.5 ns). For QD605-FMH dimers, the lifetime histograms are asymmetric and with peak values diminished to 5 ns (σ˜6.7 ns) for QD605-16AHT-FMH, 3 ns (σ˜5.9 ns) for QD605-11AUT-FMH, and 1 ns (σ˜4.4 ns) for QD605-6AHT-FMH, indicating enhanced electron transfer by reducing linker length as well as fluctuations in electron transfer rate. As a comparison, the PL lifetime histogram of individual QD605 spincoated on top of a fullerene FMH thin film is shown in FIG. 9E, featuring a peak at 20 ns (σ˜7.6 ns). This particular histogram is broader than those corresponding to Qdot-FMH dimers (see FIG. 9B-9D), but rather similar to that observed by others for individual core/shell Qdots coated on TiO₂ films. This demonstrates how the dimer structure significantly reduces the magnitude of fluctuations of ET between Qdot and FMH. Furthermore, the lifetime distributions for dimers become narrower with shorter linkers, suggesting suppression of ET fluctuations by reducing linker length. Finally, from the distributions of PL lifetimes one can calculate average ET rates to quantify the linker length effect on electron transfer rate (see FIG. 9F).

### Example 4

The unique size-dependent energy band gap of Qdots provides another effective way to control single molecule ET in quantum dot-fullerene dimer conjugates. By decreasing the quantum dot core size from 4.4 nm to 2.5 nm, the conduction band is expected to be up-lifted by around 0.2 eV, resulting in an increase of the ET driving force. This should lead to an increase in driving force and therefore an increase in ET rate.

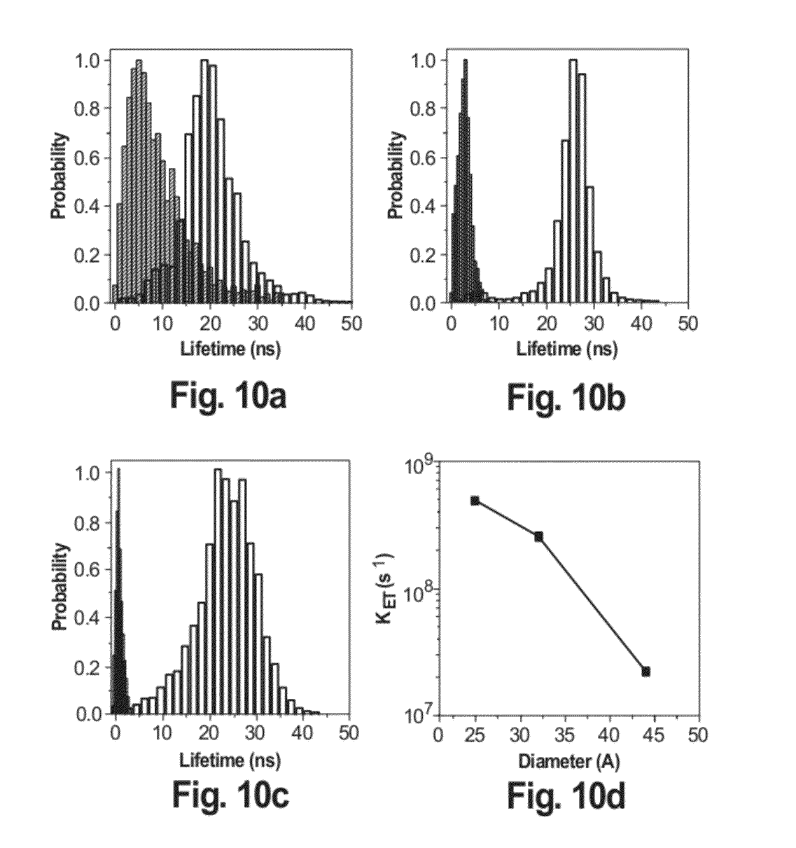

PL lifetime histograms from individual Qdot isomers and from individual quantum dot fullerene dimers of the type Qdot-16AHT-FMH and with Qdots of different colors (sizes), namely QD605 (core size 4.4 nm), QD565 (3.2 nm), and QD525 (2.5 nm), were measured and they are shown in FIGS. 10A, 10B, and 10C, respectively. FIG. 10D shows the average ET rate versus Qdot's core size calculated based on the histograms from FIGS. 10A-C. The ET rate increases from 2.2×10⁷ s⁻¹ for QD605-16AHT-FMH to 4.9×10⁸ s−1 for QD525-16AHT-FMH, consistent with the size-dependent ET observed by others for CdSe quantum dots transferring to TiO₂. One interesting phenomenon associated with the size-dependent ET rate is that ET fluctuations are suppressed in dimers with smaller Qdot size. The standard deviation of the PL lifetime is 6.7 ns for QD605-16AHT-FMH, 1.4 ns for QD565-16AHT-FMH, and 0.8 ns for QD525-16AHT-FMH, respectively, thus demonstrating control of fluctuation and magnitude of rate for ET by the use of such conjugate systems.

While the fullerene-quantum dot dimer conjugate of the present invention and the method of synthesizing the same have been described in connection with what is presently considered to be the most practical and preferred embodiments, it is to be understood that the invention is not to be limited to the disclosed embodiments, but on the contrary, is intended to cover various modifications and equivalent arrangements included within the spirit and scope of the appended claims. Other embodiments may result from a different combination of portions of different embodiments.

The description has not attempted to exhaustively enumerate all possible variations. That alternate embodiments may not have been presented for a specific portion of the invention, and may result from a different combination of described portions, or that other undescribed alternate embodiments may be available for a portion, is not to be considered a disclaimer of those alternate embodiments. It will be appreciated that many of those undescribed embodiments are within the literal scope of the following claims, and others are equivalent. Furthermore, all references, publications, U.S. patents, and U.S. patent application Publications cited throughout this specification are hereby incorporated by reference as if fully set forth in this specification.

1. A semiconducting conjugate dimer, comprising:
a quantum dot;
a fullerene; and
a covalent linker formed between the quantum dot and the fullerene.

2. The semiconducting conjugate dimer as recited in claim 1, wherein the covalent linker is an aminoalkanethiol.

3. The semiconducting conjugate dimer as recited in claim 1, wherein each conjugate has one quantum dot, one fullerene and one linker.

4. The semiconducting conjugate dimer as recited in claim 1, wherein each conjugate has one quantum dot, one fullerene and two or more linkers.

5. The semiconducting conjugate dimer as recited in claim 1, wherein the quantum dot comprises a core.

6. The semiconducting conjugate dimer as recited in claim 5, wherein the quantum dot further comprises a shell surrounding the core.

7. The semiconducting conjugate dimer as recited in claim 5, wherein the core of the quantum dot is made from a homogeneous material that is crystalline, polycrystalline, or amorphous.

8. The semiconducting conjugate dimer as recited in claim 5, wherein the core of the quantum dot comprises at least one inorganic crystal of Group IV semiconductor materials.

9. The semiconducting conjugate dimer as recited in claim 8, wherein the Group IV semiconductor materials are selected from Si, Ge, C, and mixtures thereof.

10. The semiconducting conjugate dimer as recited in claim 5, wherein the core of the quantum dot comprises at least one inorganic crystal of Group II-VI semiconductor materials.

11. The semiconducting conjugate dimer as recited in claim 10, wherein the Group II-VI semiconductor materials are selected from ZnS, ZnSe, ZnTe, ZnO, CdS, CdSe, CdTe, CdO, HgS, HgSe, HgTe, HgO, MgS, MgSe, MgTe, MgO, CaS, CaSe, CaTe, CaO, SrS, SrSe, SrTe, SrO, BaS, BaSe, BaTe, BaO, and mixtures thereof.

12. The semiconducting conjugate dimer as recited in claim 5, wherein the core of the quantum dot comprises at least one inorganic crystal of Group III-V semiconductor materials.

13. The semiconducting conjugate dimer as recited in claim 12, wherein the Group III-V semiconductor materials are selected from AlN, AlP, AlAs, AlSb, GaN, GaP, GaAs, GaSb, InN, InP, InAs, InSb, and mixtures thereof.

14. The semiconducting conjugate dimer as recited in claim 5, wherein the core of the quantum dot comprises at least one inorganic crystal of Group IV-VI semiconductor materials.

15. The semiconducting conjugate dimer as recited in claim 14, wherein the Group IV-VI semiconductor materials are selected from PbS, PbSe, PbTe, PbO, and mixtures thereof.

16. The semiconducting conjugate dimer as recited in claim 6, wherein the shell of the quantum dot is made from an inorganic semiconductor with a bandgap that is larger than that of the core material.

17. The semiconducting conjugate dimer as recited in claim 6, wherein the shell of the quantum dot comprises at least one inorganic crystal of Group II-VI semiconductor materials.

18. The semiconducting conjugate dimer as recited in claim 17, wherein the Group II-VI semiconductor materials are selected from ZnS, ZnSe, ZnTe, ZnO, CdS, CdSe, CdTe, CdO, HgS, HgSe, HgTe, HgO, MgS, MgSe, MgTe, MgO, CaS, CaSe, CaTe, CaO, SrS, SrSe, SrTe, SrO, BaS, BaSe, BaTe, BaO, and a mixture thereof;

19. The semiconducting conjugate dimer as recited in claim 6, wherein the shell of the quantum dot comprises at least one inorganic crystal of Group 111-V semiconductor materials.

20. The semiconducting conjugate dimer as recited in claim 19, wherein the Group III-V semiconductor materials are selected from AlN, AlP, AlAs, AlSb, GaN, GaP, GaAs, GaSb, InN, InP, InAs, InSb, and a mixture thereof.

21. The semiconducting conjugate dimer as recited in claim 6, wherein the shell of the quantum dot has a thickness in the range between about 0.1 nm and about 10.0 nm.

22. The semiconducting conjugate dimer as recited in claim 1, wherein the quantum dot has a size between about 1 nm and about 100 nm in diameter.

23. The semiconducting conjugate dimer as recited in claim 1, wherein the quantum dot has a size between about 1 nm and about 50 nm in diameter.

24. The semiconducting conjugate dimer as recited in claim 1, wherein the quantum dot has a size between about 1 nm to about 20 nm in diameter.

25. The semiconducting conjugate dimer as recited in claim 1, wherein the quantum dot has a size of about 10 nm in diameter.

26. The semiconducting conjugate dimer as recited in claim 5, wherein the quantum dot further comprises a ligand layer made from one or more surface ligands.

27. The semiconducting conjugate dimer as recited in claim 1, wherein the quantum dot has a core made from CdSe, a shell surrounding the core made from ZnS and a surface ligand layer made from species with exposed carboxyl groups.

28. The semiconducting conjugate dimer as recited in claim 2, comprising a linking moiety between the quantum dot and the aminoalkanethiol linker is a bond between a sulfhydryl group of the linker and a metal present in a shell of the quantum dot in the form of a metal-ligand interaction.

29. The semiconducting conjugate dimer as recited in claim 2, wherein the aminoalkanethiol is 11-Amino-1-undecanethiol, 8-Amino-1-octanethiol, 6-Amino-1-hexanethiol, 16-Amino-1-hexadecanethiol, Amino-EG6-undecanethiol, or Amino-EG6-hexadecanethiol.

30. The semiconducting conjugate dimer as recited in claim 1, wherein the fullerene comprises a fullerene core and one or more functional groups linked to the fullerene core.

31. The semiconducting conjugate as recited in claim 30, wherein the fullerene core is C₆₀, C₇₀, C₇₆, C₈₀, C₈₄, or C₁₂₀.

32. The semiconducting conjugate dimer as recited in claim 30, wherein the functional group is a compound with an exposed carboxyl, amino, or hydroxyl group.

33. The semiconducting conjugate dimer as recited in claim 30, wherein the fullerene is C₆₀(—COOH)₄₋₈.

34. The semiconducting conjugate dimer as recited in claim 30, wherein the fullerene is functionalized with a dicarboxylic acid.

35. The semiconducting conjugate dimer as recited in claim 34, wherein the dicarboxylic acid is a malonic acid, a glutaric acid, a pimelic acid, an azelaic acid, or a combination thereof.

36. The semiconducting conjugate dimer as recited in claim 35, wherein the fullerene is C₆₀ functionalized with malonic acid hexadduct of formula C₆₀[C(COOH)₂]₆.

37. The semiconducting conjugate dimer as recited in claim 1, wherein the conjugate is immobilized on a solid support.

38. The semiconducting conjugate dimer as recited in claim 37, wherein the solid support is made from an insoluble material.

39. The semiconducting conjugate dimer as recited in claim 38, wherein the insoluble material is a silicon oxide, metal oxide, or a mixture thereof.

40. The semiconducting conjugate dimer as recited in claim 39, wherein the silicon oxide material is selected from the group consisting of glass, fused quartz, fumed silica, and colloidal silica.

41. A method of synthesizing a quantum dot-fullerene conjugate dimer on a solid support, the method comprising:
(i) preparing a surface of a solid support;
(ii) activating the surface;
(iii) immobilizing a fullerene or a derivative thereof on the activated surface by a covalent linkage;
(iv) covalently bonding one end of a linker to the immobilized fullerene; and
(v) covalently attaching a quantum dot to the opposite end of the linker to produce a quantum dot-fullerene conjugate dimer immobilized on the surface of the solid support.

42. The method of claim 41, wherein the solid support is made from an insoluble material.

43. The method of claim 42, wherein the insoluble material is a silicon oxide, metal oxide or a mixture thereof.

44. The method of claim 43, wherein the silicon oxide material is selected from the group consisting of glass, fused quartz, fumed silica, and colloidal silica.

45. The method of claim 41, wherein preparing the surface of the solid support comprises hydroxylating the surface.

46. The method of claim 45, wherein hydroxylating the surface comprises soaking the surface in a solution that hydroxylates the surface.

47. The method of claim 46, wherein the solution that hydroxylates the surface is a Piranha solution made from a mixture of hydrogen peroxide (H₂O₂) and sulfuric acid (H₂SO₄).

48. The method of claim 47, wherein the Piranha solution has a mixture ratio of 2:1 to 7:1 of concentrated sulfuric acid to hydrogen peroxide.

49. The method of claim 46, wherein the surface is soaked for about 5 to about 30 minutes.

50. The method of claim 49, wherein the soaking is done for about 15 minutes.

51. The method of claim 45, wherein preparing the surface of the solid support further comprises rinsing the surface with deionized water and drying.

52. The method of claim 41, wherein activating the surface comprises a process of silanization.

53. The method of claim 52, wherein the process of silanization comprises soaking the prepared surface with an activating agent to produce an organofunctional alkoxysilane surface.

54. The method of claim 53, wherein the activating agent is an aminosilane, a glycidoxysilane, or a mercaptosilane.

55. The method of claim 54, wherein the aminosilane activating agent is 3-aminopropyl-triethoxysilane (APTES), 3-aminopropyl-diethoxy-methylsilane (APDEMS), 3-aminopropyl-dimethyl-ethoxysilane (APMES), or 3-aminopropyl-trimethoxysilane (APTMS), wherein the glycidoxysilane activating agent is 3-glycidoxypropyl-dimethyl-ethoxysilane (GPMES); and wherein the mercaptosilane activating agent is 3-mercaptopropyl-trimethoxysilane (MPTS), or 3-mercaptopropyl-methyl-dimethoxysilane (MPDMS).

56. The method of claim 55, wherein the activating agent is 3-aminopropyl-trimethoxysilane (APTMS).

57. The method of claim 53, wherein activating comprises soaking the surface with the activating agent in a water-free environment for about 15 to 20 minutes.

58. The method of claim 57, wherein the step of activating further comprises heat treating the combination of the solid support and the activating agent at about 90° C. for about 1 hour.

59. The method of claim 41, wherein the step of immobilizing the fullerene comprises contacting the activated surface with a functionalized fullerene or a derivative thereof in the presence of a crosslinking agent.

60. The method of claim 59, wherein the functionalized fullerene or a derivative thereof is a fullerene with two or more exposed carboxyl groups.

61. The method of claim 41, wherein the fullerene is C₆₀, C₇₀, C₇₆, C₈₀, C₈₄, or C₁₂₀.

62. The method of claim 59, wherein the functionalized fullerene or a derivative thereof is a fullerene-malonic acid-hexadduct (FMH) of formula C₆₀[C(COOH)₂]₆.

63. The method of claim 61, wherein the crosslinking agent is 1-ethyl-3-(3-dimethylaminopropyl)carbodiimide hydrochloride (EDC).

64. The method of claim 61, wherein the immobilization step is performed for about 30 minutes.

65. The method of claim 41, wherein covalently bonding one end of the linker to the immobilized fullerene comprises treating the immobilized fullerene with a linker and a crosslinking agent.

66. The method of claim 65, wherein the linker is an aminoalkanethiol.

67. The method of claim 65, wherein the covalent bonding is performed for about 30 minutes.

68. The method of claim 65, wherein the crosslinking agent is 1-ethyl-3-(3-dimethylaminopropyl)carbodiimide hydrochloride (EDC).

69. The method of claim 66, wherein the aminoalkanethiol is selected from the group consisting of 11-Amino-1-undecanethiol hydrochloride, 8-Amino-1-octanethiol hydrochloride, 6-Amino-1-hexanethiol hydrochloride, 16-Amino-1-hexadecanethiol hydrochloride, Amino-EG6-undecanethiol hydrochloride, and Amino-EG6-hexadecanethiol. hydrochloride.

70. The method of claim 41, wherein covalently attaching the quantum dot to the immobilized linker comprises treating an immobilized linker with a carboxyl-ended water-soluble quantum dot.

71. The method of claim 41, wherein the quantum dot comprises a core.

72. The method of claim 71, wherein the quantum dot further comprises a shell surrounding the core.

73. The method of claim 71, wherein the core of the quantum dot is made from a homogeneous material that is crystalline, polycrystalline, or amorphous.

74. The method of claim 71, wherein the core of the quantum dot comprises at least one inorganic crystal of Group IV semiconductor materials.

75. The method of claim 74, wherein the Group IV semiconductor materials are selected from Si, Ge, C, and mixtures thereof.

76. The method of claim 71, wherein the core of the quantum dot comprises at least one inorganic crystal of Group II-VI semiconductor materials.

77. The method of claim 76, wherein the Group II-VI semiconductor materials are selected from ZnS, ZnSe, ZnTe, ZnO, CdS, CdSe, CdTe, CdO, HgS, HgSe, HgTe, HgO, MgS, MgSe, MgTe, MgO, CaS, CaSe, CaTe, CaO, SrS, SrSe, SrTe, SrO, BaS, BaSe, BaTe, BaO, and mixtures thereof.

78. The method of claim 71, wherein the core of the quantum dot comprises at least one inorganic crystal of Group III-V semiconductor materials.

79. The method of claim 78, wherein the Group III-V semiconductor materials are selected from AlN, AlP, AlAs, AlSb, GaN, GaP, GaAs, GaSb, InN, InP, InAs, InSb, and mixtures thereof.

80. The method of claim 71, wherein the core of the quantum dot comprises at least one inorganic crystal of Group IV-VI semiconductor materials.

81. The method of claim 80, wherein the Group IV-VI semiconductor materials are selected from PbS, PbSe, PbTe, PbO, and mixtures thereof.

82. The method of claim 72, wherein the shell of the quantum dot is made from an inorganic semiconductor with a bandgap that is larger than that of the core material.

83. The method of claim 72, wherein the shell of the quantum dot comprises at least one inorganic crystal of Group II-VI semiconductor materials.

84. The method of claim 83, wherein the Group II-VI semiconductor materials are selected from ZnS, ZnSe, ZnTe, ZnO, CdS, CdSe, CdTe, CdO, HgS, HgSe, HgTe, HgO, MgS, MgSe, MgTe, MgO, CaS, CaSe, CaTe, CaO, SrS, SrSe, SrTe, SrO, BaS, BaSe, BaTe, BaO, and a mixture thereof;

85. The method of claim 72, wherein the shell of the quantum dot comprises at least one inorganic crystal of Group 111-V semiconductor materials.

86. The method of claim 85, wherein the Group III-V semiconductor materials are selected from AlN, AlP, AlAs, AlSb, GaN, GaP, GaAs, GaSb, InN, InP, InAs, and InSb, and a mixture thereof.

87. The method of claim 72, wherein the shell of the quantum dot has a thickness in the range between about 0.1 nm and about 10 nm.

88. The method of claim 72, wherein the quantum dot has the size between about 1 nm and about 100 nm in diameter.

89. The method of claim 88, wherein the quantum dot has the size between about 1 nm and about 50 nm in diameter.

90. The method of claim 89, wherein the quantum dot has the size between about 1 nm to about 20 nm in diameter.

91. The method of claim 90, wherein the quantum dot has the size of about 10 nm in diameter.

92. The method of claim 71, wherein the quantum dot further comprises a ligand layer made from one or more surface ligands.

93. The method of claim 72, wherein the quantum dot further comprises a ligand layer made from one or more surface ligands.

94. The method of claim 41, wherein the quantum dot has a core made from CdSe, a shell surrounding the core made from ZnS, and a surface ligand layer made from species with exposed carboxyl groups.

95. The semiconducting conjugate dimer as recited in claim 6, wherein the quantum dot further comprises a ligand layer made from one or more surface ligands.
